(19) United States
(12) Patent Application Publication
(10) Pub. No.: US 2024/0368415 A1
(43) Pub. Date: Nov. 7, 2024

(54) METAL OXIDE PRECURSOR COMPOSITION

(71) Applicants: VTT Technical Research Centre of Finland Ltd, ESPOO (FI); NATIONAL INSTITUTE OF ADVANCED INDUSTRIAL SCIENCE AND TECNOLOGY, Tokyo (JP)

(72) Inventors: Yasuyuki KUSAKA, lbaraki (JP); Nobuko FUKUDA, lbaraki (JP); Mariko FUJITA, Ibaraki (JP); Jaakko LEPPANIEMI, Espoo (FI); Asko SNECK, Espoo (FI)

(21) Appl. No.: 18/568,004

(22) PCT Filed: Jun. 11, 2021
(86) PCT No.: PCT/JP2021/022297

§ 371 Date: Dec. 7, 2023

(51) Int. Cl. C09D 11/033; C09D 11/52; H01L 21/02

(52) U.S. Cl. CPC C09D 11/033; C09D 11/52; H01L 21/02554

(57) ABSTRACT

A metal oxide precursor composition includes a metal salt: a first organic solvent having a surface tension of 25 mN/m or less; and a second organic solvent having a boiling point of 100° C. or higher and a solubility parameter of 10 cal^{1/2} cm^{-3/2} or greater. The metal salt is soluble in the second organic solvent at a concentration of at least 1 mol/L.

### TECHNICAL FIELD

The present invention relates to a metal oxide precursor composition.

### BACKGROUND ART

Methods of forming a functional pattern by printing to produce electronic components or devices have been well studied because of their advantages in reduced cost and processing time over other methods such as lithography and a vacuum film formation. Among a variety of printing processes for the methods, a reverse offset printing has recently attracted a lot of attention, because it can provide a very fine pattern with a high rectangularity in cross-section. In the reverse offset printing, a precursor ink composition (functional ink) is applied on the blanket roll typically covered with silicone rubber (polydimethylsiloxane (PDMS)) to form an ink composition layer. The ink composition layer is then brought into contact with an engraved plate (cliche) to remove unnecessary parts of the ink composition layer from the PDMS blanket. Subsequently, the remainder of the ink composition layer on the cliche surface are transferred to a substrate such as silicon wafer.

The reverse offset printing uses inks containing nano-sized metal or metal oxide particles. However, the inks cannot provide a sufficient surface smoothness of the functional pattern. In particular, the nano-sized particles contained in the inks may cause surface irregularities reflected by the particle shape and increase the surface roughness. Therefore, when an additional upper film is formed on the rough surface of the pattern, the upper film cannot follow the surface line of the irregularities, particularly in case where the thickness of the upper film is equal to or less than the depth of a depression of the irregularities. This may result in an electrical disconnection in the upper film.

In addition, films derived from nano-sized metal or metal oxide particles are porous, and the porosity can be reduced only through grain-growth during annealing at high temperature. The porosity leads to large surface area which makes the material susceptible to adsorption of ambient gases and, therefore, may be detrimental to the environmental stability of the semiconductor material. Particle-derived semiconductor films are also more prone to charge trapping at the grain boundaries on the edges of the particles than uniform, dense films derived from metal oxide precursors.

Patent Literature 1 describes a functional ink suitable for offset printing to create a fine functional pattern with reduced surface roughness. The functional ink contains metal or metal oxide fine particles, a linker having a plurality of functional groups capable of interacting with the fine particles, and a solvent. However, the ink can only form a line pattern with a line width of about 20 μm, and a surface roughness of about 10 nm. Furthermore, the resulting film pattern is not particularly thin, because the thickness of the film pattern formed by the ink cannot be less than the particle diameter. Accordingly, a conventional ink as described in Patent Literature 1 cannot provide a very thin functional layer pattern, such as a tunnel layer with a thickness of several nanometers, and a charge injection layer with a desired thickness of 10 to 20 nanometers.

Patent Literature 2 describes a functional ink containing nano-sized metal particles in a low-molecular-weight hydrocarbon medium, which can suppress the surface roughness of the functional pattern. However, the ink has only limited use in ink-jet printing or flexographic printing, and is not suitable for offset printing due to its low viscosity. Further, because the ink has a high wettability and spreadability on a substrate, the resulting pattern tends to have a non-uniform thickness. It is also not easy to obtain a functional pattern with a high resolution, such as a line pattern with a line width of 20 μm or less.

Non Patent Literature 1 describes using a functional ink composition containing a metal salt for the reverse offset printing. The ink is specifically based on metal nitrates dissolved in an organic solvent. However, the ink as described in Non Patent Literature 1 needs additional thermal treatment (heating) to promote the formation of the semidry condition on the PDMS blanket for enabling the resulting patterned film to have sharp edge and a small thickness. The additional thermal treatment prevents the use of such metal salt precursor ink in continuous (roll-to-roll) reverse offset process. The additional heating can also be a source of inhomogeneity in the resulting patterned film.

### CITATION LIST

### Patent Literature

[PTL 1] Japanese Laid-open Patent Publication No. 2010-70606
[PTL 2] Japanese Laid-open Patent Publication No. 2017-33987

### Non Patent Literature

[NPTL 1] Leppaniemi, J. et al., “A. Reverse-Offset Printing of Metal Nitrate-Based Metal Oxide Semiconductor Ink for Flexible TFTs”, Advanced Electronic Materials, Volume 5, Issue 8 (2019), 1900272

### SUMMARY OF INVENTION

### Technical Problem

The present invention is made in light of the above problems. An object of the present invention is to provide a composition that is suitable for reverse offset printing, and that is capable of forming a metal oxide functional pattern with a higher resolution and improved surface smoothness.

### Solution to Problem

In order to solve the above-described problem, one aspect of the present invention is to provide a metal oxide precursor composition including a metal salt; a first organic solvent having a surface tension of 25 mN/m or less; and a second organic solvent having a boiling point of 100° C. or higher and a solubility parameter of 10 cal^{1/2} cm^{-3/2} or greater, and in which the metal salt is soluble at a concentration of at least 1 mol/L.

### BRIEF DESCRIPTION OF DRAWINGS

FIG. 1 is an optical microscope photograph of the functional pattern formed on the silicon wafer in Example 1.

FIG. 2 is an optical microscope photograph of the functional pattern formed on the silicon wafer in Example 2.

FIG. 3 is an optical microscope photograph of the functional pattern formed on the silicon wafer in Example 3.

FIG. 4 is an optical microscope photograph of the functional pattern formed on the silicon wafer in Example 4.

FIG. 5 is an optical microscope photograph of the functional pattern formed on the silicon wafer in Example 5.

FIG. 6 is an optical microscope photograph taken after the composition of Comparative Example 1 is applied to the silicone rubber sheet.

FIG. 7 is an optical microscope photograph of the functional pattern formed on the silicon wafer in Comparative Example 2.

### DESCRIPTION OF EMBODIMENTS

An embodiment of the present invention provides a metal oxide precursor composition including a metal salt; a first organic solvent having a surface tension of 25 mN/m or less; and a second organic solvent having a boiling point of 100° C. or higher and a solubility parameter of 10 cal^{1/2} cm^{-3/2} or greater, and in which the metal salt is soluble at a concentration of at least 1 mol/L. The metal oxide precursor composition can be printed in a particular pattern on a substrate, preferably by reverse offset printing, and then thermally treated for drying and baking to form a metal oxide functional pattern on the substrate. In the thermal treatment, the metal salt in the composition is oxidized to produce a metal oxide.

The metal oxide to be produced on the substrate may be any of the metal oxides which can form an oxide semiconductor or oxide dielectric used for electronic components or devices. Specific examples of the metal oxide include aluminum oxide, indium oxide, zinc oxide, copper oxide, nickel oxide, cadmium oxide, gallium oxide, mixed oxides of indium and zinc, mixed oxides of rhodium and zinc, mixed oxides of copper and aluminum, and mixed oxides of copper and strontium. The above metal oxides are useful for producing metal oxide semiconductor devices, including transistors, memories, gas sensors, and optical sensors.

The composition according to the present embodiment includes a metal salt as a metal oxide precursor. Specific examples of the metal salt include salts of aluminum, titanium, indium, zinc, copper, nickel, cadmium, gallium, tin, rhodium, and strontium. Among these, salts of one or more metals selected from titanium, indium, zinc, and gallium are preferable, because they allow the resulting metal oxide semiconductor devices to have an excellent semiconductor performance.

The metal salt may include a nitrate, a chloride, a sulfate, a sulfide, an acetate, a phosphate, a carbide, iodide, and preferably a nitrate, because they have relatively good dispersibility in the organic solvents described in detail below. In addition, in the thermal treatment process after printing, a residue (remained nitrate), which can become a trap site, is relatively easily removed at a lower temperature. The counter ion in metal nitrates (NO₃⁻) is more volatile and easier to remove when compared to the counter ions from other metal salts.

According to the present embodiment, the metal salt is dissolved in the composition, that is, the metal is contained in an ionized form in the composition, and not in the form of solid particles. This results in a reduced thickness and a reduced surface roughness of the resulting functional pattern, compared with conventional compositions containing nano-sized solid metal or metal oxide particles.

In addition, nano-sized particles are usually costly, and therefore the composition using metal salt according to the present embodiment can reduces a manufacturing cost of the metal oxide semiconductor devices. Furthermore, because conventional nanosized particles have a large specific surface area and are easily oxidizable, usable metals or metal oxides are limited to those less easily oxidizable. In contrast, the composition of the present embodiment using a metal salt, which is generally chemically more stable, allows a wider choice of materials.

The content of the metal salt in the composition of the present embodiment is preferably 1 to 20% by weight, more preferably 5 to 10% by weight, with respect to a total amount of the metal oxide precursor composition. When the content of the metal salt is 1% by weight or more, defects (gaps or holes) in the resulting metal oxide functional pattern can be reduced. When the content of the metal salt is 20% by weight or less, the viscosity of the composition does not become too high, thereby allowing the formation of a fine functional pattern, or a pattern with a high resolution.

According to the present embodiment, the metal salt is dissolved in at least two kinds of solvents. The first solvent is an organic solvent having a surface tension of 25 mN/m or less, and the second solvent is an organic solvent having a boiling point of 100° C. or higher and a solubility parameter of 10 cal^{1/2} cm^{-3/2} or greater, and in which the metal salt is soluble at a concentration of at least 1 mol/L. The combination of the solvents enables the metal oxide precursor composition to have improved rheological properties, especially suitable for reverse offset printing.

In reverse offset printing, a blanket roll cover with silicone rubber (polydimethylsiloxane (PDMS)) sheet is typically used. To form a metal oxide functional pattern, first, a metal oxide precursor composition (a functional ink) is applied on the silicone rubber sheet to form an ink composition layer. The ink composition layer is then brought into contact with an engraved plate (cliche) to remove unnecessary parts of the ink composition layer from the silicone rubber sheet. Subsequently, the remainder of the ink composition layer on the cliche surface are transferred to a substrate such as silicon wafer.

The first organic solvent contained in the composition or the present embodiment, which has a surface tension of 25 mN/m or less, preferably 23 mN/m or less, more preferably 20 mN/m or less, and more preferably 19 mN/m or less. The first organic solvent having the above surface tension ensures that the composition will have sufficient wettability to form a thinner and more uniform ink layer on the silicone rubber sheet. Thus, the thickness of the resulting metal oxide functional pattern will be thinner and more uniform. In this specification, the surface tension is the value measured at 25° C.

The lower limit of the surface tension of the first organic solvent is not particularly limited, but may preferably be 16 mN/m or more in light of improvement in miscibility with other solvents.

The first organic solvent may be at least one solvent selected from fluorine-containing alcohols (alcohols in which a part of hydrogen is substituted with fluorine) and lower aliphatic alcohols having a boiling point 100° C. or lower. The oxygen atom in the fluorine-containing alcohol molecule has a lower electron-donating property than that in an alcohol not substituted with fluorine, because of a great electron-withdrawing property of the fluorine. It is thus assumed that the fluorine-containing alcohol has a low coordination ability to a metal ion. Therefore, in the thermal treatment process to oxidize the metal, only a small amount of energy is necessary for separating the fluorine-containing alcohol molecule from the metal ion, thereby allowing the process temperature to be lowered.

Specific examples of the fluorine-containing alcohol include 2,2,2-trifluoroethanol, 2,2-difluoroethanol, and 2,2,3,3,3-pentafluoro-1-propanol. Among these solvents, 2,2,2-trifluoroethanol is particularly preferable, because of its lower surface tension than the others. The above-mentioned solvents may be used alone or in combination of two or more.

The lower aliphatic alcohol having a boiling point 100° C. or lower used as the first solvent is preferably a monovalent linear or branched alcohol having 1 to 3 carbons. The lower limit of the boiling point of the lower aliphatic alcohol is not particularly limited, but it may preferably be equal to or higher than room temperature (15 to 25° C.) so that the solvent can be more easily handled.

Specific examples of the lower aliphatic alcohol include methanol, 1-propanol, 2-propanol, and ethanol. Among these, methanol is preferable due to its low boiling point and good absorbability into silicone. The above specific solvents may be used alone or in combination of two or more.

The content of the first solvent in the metal oxide precursor composition is preferably 65 to 95% by weight, and more preferably 70 to 90% by weight, with respect to a total amount of the metal oxide precursor composition. The content of the first solvent being 65% by weight or more can increase a wettability of the metal oxide precursor composition, so that the applied ink composition layer on the silicone rubber has a uniform and reduced thickness. The content of the first solvent being 95% by weight or less enables a formation of a finer functional pattern (a functional pattern with higher resolution).

In reverse offset printing, solvents contained in the ink composition are at least partially absorbed into the silicone rubber and/or volatilized. This result in solidification of the applied ink layer to a certain degree, which allows for patterning when the ink layer is brought in contact with the cliche surface. However, when the ink composition is absorbed into the silicone rubber and/or volatilized too rapidly, the metal salt can be crystallized out and the desired pattern cannot be formed on the cliche surface. Additionally, when both the volatility and the absorption of the solvent to PDMS are too low, an additional heating step is may be needed to promote the formation of the semi-dry ink state on the PDMS blanket. This prevents the use of continuous reverse offset printing process.

In the present embodiment, the second organic solvent is added so as to control the solidification of the metal oxide precursor composition. Because the second organic solvent has a boiling point of 100° C. or higher, the second organic solvent itself is not easily volatilized in the printing process, and prevents the composition from drying out too rapidly. The upper limit of the boiling point of the second organic solvent is not particularly limited, but may preferably be 250° C., so that so that the second organic solvent can be volatilized at an appropriate rate in a subsequent sintering process (thermal treatment).

The second organic solvent also has a solubility parameter (Hildebrand parameter) of 10 cal^{1/2} cm^{-3/2} or more. This prevents the solvents in the composition from being absorbed too rapidly into the silicone rubber. In the specification, the solubility parameter is the value measured at 25° C. The upper limit of the solubility parameter of the second organic solvent is not particularly limited, but may preferably be 15 cal^{1/2} cm^{-3/2} so that the metal oxide precursor composition can be appropriately adhered to the silicone rubber sheet, and also dewetting of the film pattern can be prevented.

Accordingly, the second organic solvent can control a drying or solidifying property (including drying rate) of the metal oxide precursor composition on the blanket roll (silicone rubber sheet). The second organic solvent also has a high compatibility with the first organic solvent.

In addition, the second organic solvent has an enhanced ability to dissolve the metal salt. Specifically, the metal salt is soluble at a concentration of at least 1 mol/L in the second organic solvent. Therefore, the metal salt can be dissolved homogeneously in the composition at an increased concentration. This allows the resulting functional pattern to have a reduced surface roughness. The solubility of the metal salt in the second organic solvent is preferably 1.5 mol/L or more, more preferably 2 mol/L or more. The upper limit of the solubility of the metal salt in the second organic solvent is not particularly limited, but may usually be approximately 10 mol/L. In the specification, the solubility of the metal oxide is the value measured at 25° C.

Furthermore, the metal salt dissolved in the second organic solvent at a high concentration provides the composition with a good rheological property (viscoelasticity) suitable for reverse offset printing.

Examples of the second organic solvent includes divalent alcohols such as ethylene glycol, and 1,3-propanediol; lower alcohols such as 1-butanol, 2-butanol, and 3-methyl-1-butanol; alkoxy ethanols such as 2-methoxyethanol, and 2-ethoxyethanol; esters of a lower alcohol and a lower carbonic acid, such as methyl methoxyacetate, butyl acetate, ethyl lactate, and ethyl butyrate. Among these, 2-methoxyethanol or methyl methoxyacctate may be preferably used. The above-mentioned solvents may be used alone or in combination of two or more.

The content of the second organic solvent in the metal oxide precursor composition is preferably 0.5 to 10% by weight, more preferably 1 to 5% by weight, with respect to a total amount of the metal oxide precursor composition. The content of the second solvent in the above range allows the solidification rate of the metal oxide precursor composition on the blanket roll (silicone rubber sheet) to be successfully controlled, and provides a patterned ink film by reverse offset printing.

The amount of the second organic solvent is preferably 0.005 to 0.5 parts by weight, and more preferably 0.01 to 0.3 parts by weight, with respect to 1 part by weight of the first solvent.

The embodiments of the present invention use a co-solvent system including the first solvent and the second solvent as described above. Such system leads to the semi-dry ink condition on PDMS blanket at or near room-temperature, and allows the potential use of a continuous reverse offset printing process (such as roll to roll process).

When the metal oxide precursor composition has a rheological property to form a layer with a thickness of 10 to 20 nm after drying, when applied on a silicone rubber sheet by a capillary coater at an application speed of 5 mm/sec.

Another embodiment of the present invention provides a method of forming a metal oxide functional pattern for a metal oxide semiconductor device through reverse offset printing, the method includes applying a metal oxide precursor ink composition as described above on a silicone rubber sheet to form an ink composition layer; forming an ink composition pattern by pressing a cliche to the ink composition layer and removing the cliche; transferring the ink composition pattern to a substrate; and chemically altering the ink composition pattern to form a metal oxide functional pattern.

Prior to the application of the metal oxide precursor ink composition on the silicone rubber sheet, the silicone rubber surface can preferably be treated by vacuum ultraviolet light irradiation, oxygen plasma treatment, ozone treatment, corona discharge treatment, or the like. The above treatment allows the surface to be more lyophilic and may prevent the ink composition from being repelled.

For altering the ink composition pattern to the metal oxide functional pattern, the transferred ink composition pattern can be subjected to a thermal annealing process, an oxygen plasma treatment, an ultraviolet treatment, or a combination thereof. The ink composition pattern (printed metal salt pattern) can also be subjected to a conventional reduction treatment such as a hydrogen plasma treatment, an argon plasma treatment, an exposing process to formic acid vapor, or a thermal treatment in a nitrogen or an atmosphere with a low oxygen partial pressure. To facilitate the chemical alteration, at least one of the solvents in the composition preferably has a reduced electron-donating property, and specifically, a donor number of 20 or less.

### EXAMPLES

### <Preparation of Functional Inks>

Metal oxide precursor compositions of Examples 1-5 and Comparative Examples 1 and 2 were prepared as follows.

### Example 1

The metal oxide precursor composition of a functional ink of Example 1 was prepared by mixing 0.1 parts by weight of aluminum nitrate, 1 part by weight of 2-2-2-trifluoroethanol, 0.03 parts by weight of 2-methoxyethanol, and 0.1 parts by weight of methanol.

### Example 2

The metal oxide precursor composition of a functional ink of Example 2 was prepared by mixing 0.1 parts by weight of aluminum nitrate, 1 part by weight of 2-2-2-trifluoroethanol, 0.03 parts by weight of methyl methoxyacetate and 0.1 parts by weight of methanol.

### Example 3

The metal oxide precursor composition of a functional ink of Example 3 was prepared by mixing 0.1 parts by weight of indium nitrate, 1 part by weight of 2-2-2-trifluoroethanol, 0.03 parts by weight of 2-methoxyethanol, and 0.1 parts by weight of methanol were mixed to prepare a functional ink (a metal oxide precursor composition).

### Example 4

The metal oxide precursor composition of a functional ink of Example 4 was prepared by mixing 0.1 parts by weight of indium nitrate, 1 part by weight of 2-2-2-trifluoroethanol, 0.03 parts by weight of methyl methoxyacetate, and 0.1 parts by weight of methanol.

### Example 5

The metal oxide precursor composition of a functional ink of Example 5 was prepared by mixing 0.1 parts by weight of indium nitrate, 1.1 parts by weight of methanol, and 0.02 parts by weight of 2-methoxyethanol.

### Comparative Example 1

The metal oxide precursor composition of a functional ink of Comparative Example 1 was prepared by mixing 0.1 parts by weight of aluminum nitrate, 1 part by weight of 2-2-2-trifluoroethanol, and 0.1 parts by weight of methanol.

### Comparative Example 2

The metal oxide precursor composition of a functional ink of Comparative Example 1 was prepared by mixing 0.1 parts by weight of indium nitrate, and 1.1 parts by weight of methanol.

### <Functional Pattern Formation>

Each functional ink was printed on a substrate to form a functional thin-film pattern by a reverse offset printing apparatus. A silicone rubber sheet included in the machine had a thickness of 25 μm (“KE106” manufactured by Shin-Etsu Chemical Co., Ltd.). The silicone rubber sheet was heated and cured, and further hydrophilized by oxygen plasma before use. Each functional ink prepared in Examples 1-5 and Comparative Examples 1 and 2 was applied on the cured silicone rubber sheet using a slit coater. During the coating, the drying of the ink layer was facilitated by heated air flow at around 100° C. using a blower. The composition of Comparative Example 2 could not be applied on the sheet, because the salt could not be sufficiently dissolved in the solvent.

Then, a cliche (engraved plate) was pressed against the surface coated with the functional ink. On the cliche, 5 μm-side square depressions spaced apart by 5 μm were formed by dry etching a silicon wafer. When the cliche was removed, unnecessary parts of the functional ink coating were also removed, thereby forming an ink pattern on the silicone rubber sheet. Subsequently, the ink pattern was transferred from the silicone rubber sheet onto a flat silicon wafer. The ink pattern was baked at 300° C. for 1 hour to form a metal oxide functional pattern.

### <Results>

### (Observation)

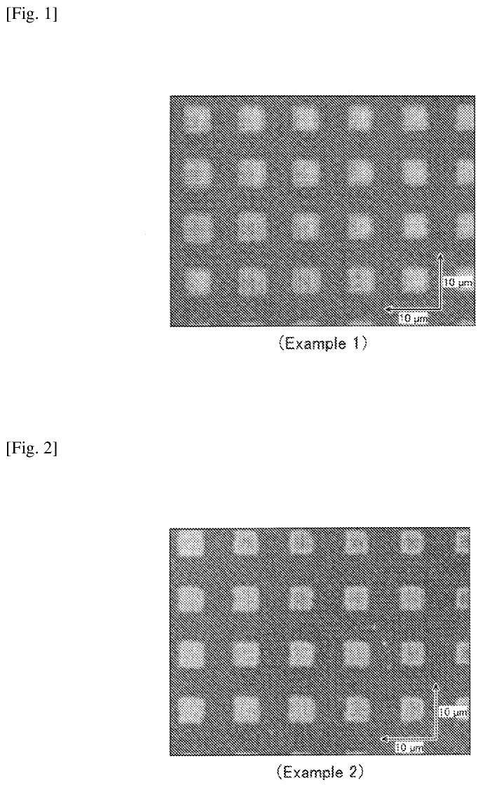

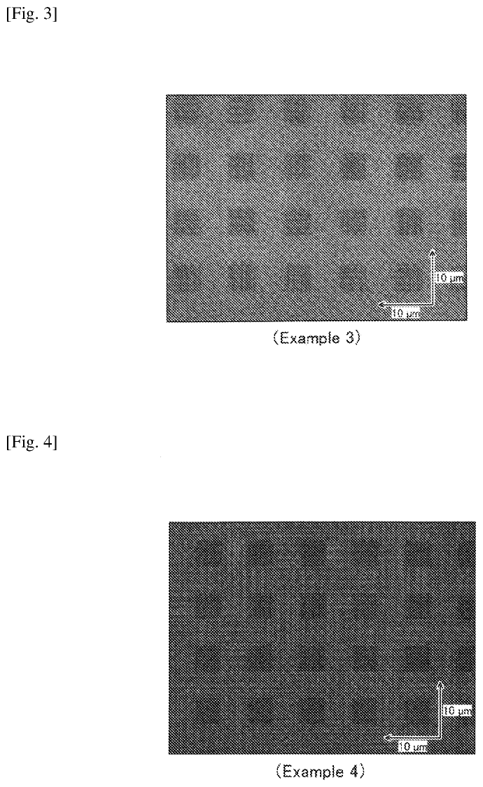

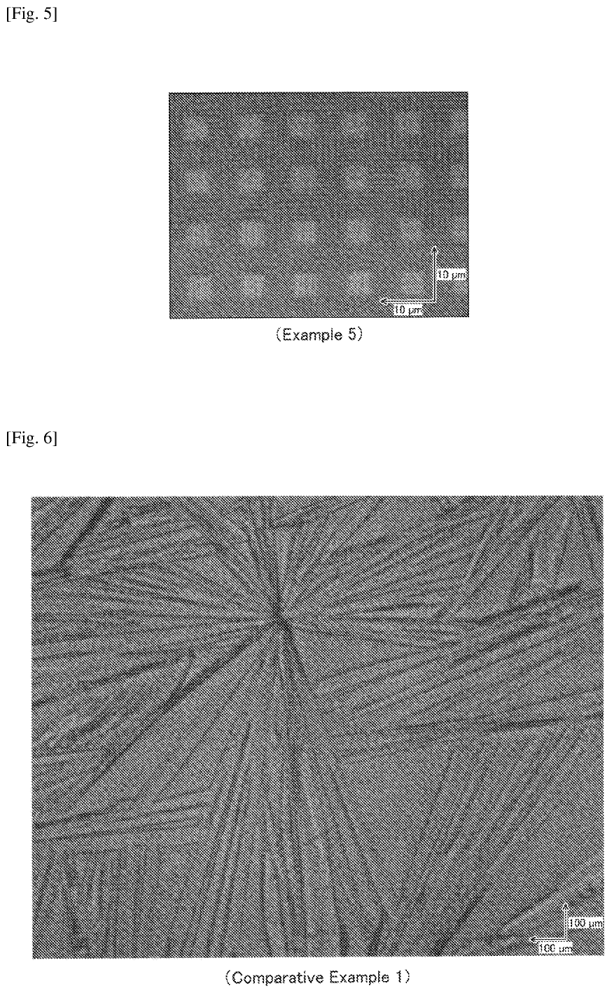

The resulting functional patterns formed on the silicon wafer by using compositions of Examples 1-5 were each observed by an optical microscope. For each of Examples 1-5, formation of a 5 μm-side square pattern on the silicon wafer (a patter with a resolution of 5 μm) was observed. FIGS. 1-5 each show a photograph of the pattern on the silicon wafer formed by using the functional ink of Examples 1-5.

In contrast, the ink composition of Comparative Example 1 was rapidly dried and the metal salt was crystallized out on the silicone rubber sheet. When the cliche is pressed against the ink layer, the ink did not adhere to the surface of the cliche at all, and thus, a pattern was not formed. FIG. 6 shows a photograph of the applied functional ink of Comparative Example 1 on the silicone rubber. Crystallized aluminum nitrate was observed.

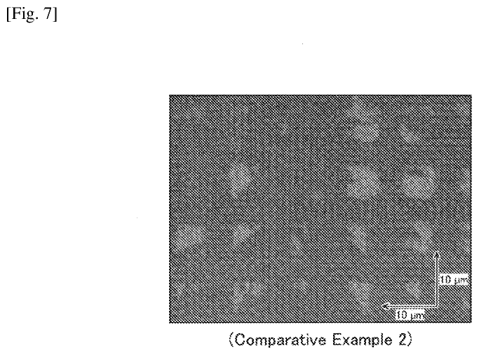

FIG. 7 shows a photograph of the pattern formed by using the functional ink of Comparative Example 2. As shown in FIG. 7, a pattern can be observed, but the pattern was not a sharp, square pattern.

### (Surface Roughness)

The surface roughnesses (Ra) of the functional patterns on the silicon wafer in Examples 1-5 were each measured by an atomic force microscope “5600 LSP” manufactured by Agilent Technologies, Inc. The results are shown in Table 1. As shown in Table 1, each of Examples 1-5 provides a low surface roughness Ra of the resulting functional pattern.

TABLE 1

| | | Example 1 | | Example 2 | | Example 3 | | Example 4 |
|---|---|---|---|---|---|---|---|---|
| | | (prts by | (% by | (prts by | (% by | (prts by | (% by | (prts by |
| Component | | weight) | weight) | weight) | weight) | weight) | weight) | weight) |
| Metal Salt | aluminum nitrate | 0.1 | 8.1 | 0.1 | 8.1 | — | — | — |
| | indium nitrate | — | — | — | — | 0.1 | 8.1 | 0.1 |
| First Solvent | 2-2-2-trifluoroethanol | 1 | 81.3 | 1 | 81.3 | 1 | 81.3 | 1 |
| | methanol | 0.1 | 8.1 | 0.1 | 8.1 | 0.1 | 8.1 | 0.1 |
| Second Solvent | 2-methoxyethanol | 0.03 | 2.4 | — | — | 0.03 | 2.4 | — |
| | methyl methoxyacetate | — | — | 0.03 | 2.4 | — | — | 0.03 |

| | | | | | | | |
|---|---|---|---|---|---|---|---|
| Total | 1.23 | 100 | 1.23 | 100 | 1.23 | 100 | 1.23 |

| | | | | |
|---|---|---|---|---|
| Pattern Formation | successful | successful | successful | successful |
| Resolution of Pattern (μm) | 5 | 5 | 5 | 5 |
| Surface Roughness Ra (nm) | 0.9 | 0.4 | 0.2 | 0.6 |

| | | | | | Comparative | | Comparative | |
|---|---|---|---|---|---|---|---|---|
| | | Example 4 | Example 5 | | Example 1 | | Example 2 | |
| | | (% by | (prts by | (% by | (prts by | (% by | (prts by | (% by |
| Component | | weight) | weight) | weight) | weight) | weight) | weight) | weight) |
| Metal Salt | aluminum nitrate | — | — | — | 0.1 | 8.3 | — | — |
| | indium nitrate | 8.1 | 0.1 | 8.2 | — | — | 0.1 | 8.3 |
| First Solvent | 2-2-2-trifluoroethanol | 81.3 | — | — | 1 | 83.3 | — | — |
| | methanol | 8.1 | 1.1 | 90.2 | 0.1 | 8.3 | 1.1 | 91.7 |
| Second Solvent | 2-methoxyethanol | — | 0.02 | 1.6 | — | — | — | — |
| | methyl methoxyacetate | 2.4 | — | — | — | — | — | — |

| | | | | | | | |
|---|---|---|---|---|---|---|---|
| Total | 100 | 1.22 | 100 | 1.2 | 100 | 1.2 | 100 |

| | | | | |
|---|---|---|---|---|
| Pattern Formation | successful | successful | no pattern | unsuccessful |
| Resolution of Pattern (μm) | 5 | 5 | N/A | N/A |
| Surface Roughness Ra (nm) | 0.6 | 0.5 | N/A | N/A |

As shown in Table 1 and FIGS. 1-7, the above-described solvent combination (the first solvent and the second solvent) enables the functional pattern to have a high resolution and a smooth surface.

It is understood that the examples and embodiments described herein are for illustrative purposes only and that various modifications or changes in light thereof will be suggested to persons skilled in the art and are to be included within the spirit and purview of this application and scope of the appended claims.

1. A metal oxide precursor composition comprising:
a metal salt;
a first organic solvent having a surface tension of 25 mN/m or less at 25° C.; and
a second organic solvent having a boiling point of 100° C. or higher and a solubility parameter of 10 cal^{1/2} cm^{-3/2} or greater,
wherein the metal salt is soluble in the second solvent at a concentration of at least 1 mol/L.

2. The metal oxide precursor composition according to claim 1, wherein the first organic solvent is at least one solvent selected from the group consisting of fluorine-containing alcohols and lower aliphatic alcohols having a boiling point 100° C. or lower.

3. The metal oxide precursor composition according to claim 2, wherein the first organic solvent is at least one solvent selected from the group consisting of 2,2,2-trifluoroethanol, 2,2-difluoroethanol, 2,2,3,3,3-pentafluoro-1-propanol, methanol, 1-propanol, 2-propanol, and ethanol.

4. The metal oxide precursor composition according to claim 1, wherein the second organic solvent is at least one selected from the group consisting of ethylene glycol, 1,3-propanediol, 2-methoxyethanol, 2-ethoxyethanol, 1-butanol, 2-butanol, 3-methyl-1-buthanol, butyl acetate, ethyl lactate, ethyl butyrate, and methyl methoxy acetate.

5. An ink for producing a metal oxide semiconductor device by reverse offset printing, comprising the metal oxide precursor composition according to claim 1.

6. An electronic device manufactured by printing a film pattern on a substrate by using ink comprising a metal salt; a first organic solvent having a surface tension of 25 mN/m or less at 25° C.; and a second organic solvent having a boiling point of 100° C. or higher and a solubility parameter of 10 cal^{1/2} cm^{-3/2} or greater, wherein the metal salt is soluble in the second solvent at a concentration of at least 1 mol/L.
